(19) United States
(12) Patent Application Publication
(10) Pub. No.: US 2006/0291168 A1
(43) Pub. Date: Dec. 28, 2006

(54) Heat dissipating module and heat sink assembly using the same

(75) Inventor: Hsin-Ho Lee, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/438,060

(22) Filed: May 18, 2006

(30) Foreign Application Priority Data
Jun. 24, 2005 (CN) 200510035547.6

(51) Int. Cl. H05K 7/20

(52) U.S. Cl. 361/701

(57) ABSTRACT

A heat dissipating module (10) includes a container (11), a wick layer (12) and a working fluid (40). The container further includes a partition wall (13), a first cavity (16), a second cavity (17), an inlet (14) and an outlet (15). The first and second cavities are separated by the partition wall. The partition wall is arranged inside the container and is configured for blocking the working fluid from flowing from the first cavity to the second cavity. The wick layer is formed as a porous capillary structure. The wick layer is configured for guiding the working liquid to flow from the first cavity to the second cavity. The present invention also provides a heat sink assembly (100). The heat sink assembly includes an above-described heat dissipating module, a circulatory tube (20) and a cooling device (30).

### BACKGROUND

1. Field of the Invention

The invention relates generally to heat sink modules, and more particularly to a heat dissipating module and a heat sink assembly using the same for efficiently removing heat generated by electronic devices such as a central processing units (CPUs).

2. Discussion of Related Art

Effective dissipation of heat produced by electronic components is an important factor in optimizing circuit performance. In addition to optimizing performance, effective heat dissipation also helps to prolong the useful life of those components. Heat dissipation is particularly important in the case of high-power electronic components. During operation of an electronic device such as a computer central processing unit (CPU), a large amount of heat is often produced. The heat must be quickly removed from the CPU to prevent it from becoming unstable or being damaged.

Typically, a heat sink is attached to an outer surface of the CPU to facilitate removal of heat therefrom. A traditional heat sink, for example, includes a core structure upon which fins are mounted. The core structure is suitably thermally coupled with the electrical component that the heat sink is intended to cool. As a result, the thermal energy passes from the electrical component to the core structure. In turn, the thermal energy passes from the core structure to the fins of the heat sink. The thermal energy is dissipated from the fins using a suitable medium running over the fins, such as air or a liquid.

However, in a manner similar to the electrical components themselves, there is a desire to decrease the size of the heat sinks. This decrease in size of a heat sink is balanced with a concern that the decreased size heat sink will not be able to sufficiently cool an electrical component. These heat sinks are inadequate to dissipate heat generated by high power electronics, despite the improvements which are being made.

Finding suitable heat sinks to adequately dissipate the heat generated by the electronic components is a difficult task. Most conventional heat dissipation methods use a liquid coolant to remove the heat generated by high-power electronic components. After absorbing the heat generated by the electronic components, the coolant will enter a vapor phase. Because the vapor is mixed with the coolant, the flow rate of the vapor will slow down. This problem reduces the heat dissipation efficiency of the coolant.

What is needed, therefore, is a heat dissipating device which can overcome the above-described disadvantages of the related art.

### SUMMARY

The present invention provides a heat dissipating module. In one embodiment, the heat dissipating module includes a container, a wick layer and a working fluid. The container further includes a partition wall, a first cavity, a second cavity, an inlet and an outlet. The first and second cavities are separated by the partition wall. The partition wall is arranged inside the container, configured for blocking the working fluid from flowing from the first cavity to the second cavity. The wick layer is formed as a porous capillary structure. The wick layer is configured for guiding the working liquid to flow from the first cavity to the second cavity.

The present invention also provides a heat sink assembly. In one embodiment, the heat sink assembly includes the above-described heat dissipating module, a circulatory tube and a cooling device. The circulatory tube has one end thereof inserted into an inlet of the heat dissipating module and another end thereof inserted into an outlet of the heat dissipating module. A working liquid flows from the circulatory tube into the heat dissipating module and then takes away the generated heat of the electronic device. Finally, the working liquid goes into the cooling device and dissipates heat to surroundings.

Advantages and novel features of the present heat dissipating module and heat sink assembly using the same will become more apparent from the following detailed description of preferred embodiments when taken in conjunction with the accompanying drawings.

### BRIEF DESCRIPTION OF THE DRAWINGS

Many aspects of the present heat dissipating module and heat sink assembly can be better understood with reference to the following drawings. The components in the drawings are not necessarily drawn to scale, the emphasis instead being placed upon clearly illustrating the principles of the present heat dissipating module and heat sink assembly.

FIG. 1 is a schematic, cross-sectional view of a heat dissipating module in accordance with a preferred embodiment of the present invention; and

FIG. 2 is an isometric view of a heat sink assembly using the heat dissipating module of FIG. 1 in accordance with a preferred embodiment of the present invention.

Corresponding reference characters indicate corresponding parts throughout the several views. The exemplifications set out herein illustrate at least one preferred embodiment of the present heat sink assembly, in one form, and such exemplifications are not to be construed as limiting the scope of the invention in any manner.

### DETAILED DESCRIPTION OF PREFERRED EMBODIMENTS

Reference will now be made to the drawings to describe embodiments of the present heat dissipating module and heat sink assembly using the same, in detail.

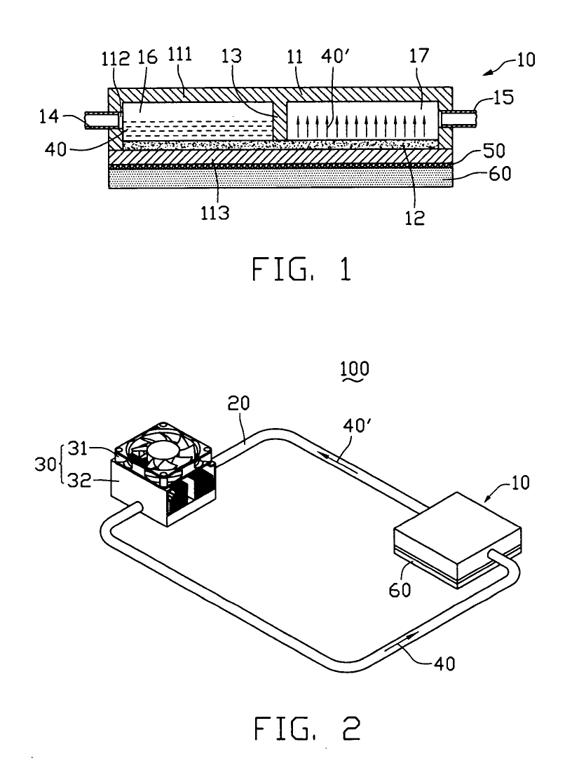

Referring to FIG. 1, a heat dissipating module 10 according to a preferred embodiment is shown. The heat dissipating module 10 includes a container 11, a wick layer 12 and a working fluid 40. The container 11 is comprised of a metal selected from the group consisting of copper, aluminum, nickel, stainless steel and any combination alloy thereof. The container 11 further includes a partition wall 13, a first cavity 16, a second cavity 17, an inlet 14 and an outlet 15. The first cavity 16 and second cavity 17 are separated by the partition wall 13. The partition wall 13 is arranged inside the container 11, and is configured for blocking the working fluid 40 from flowing from the first cavity 16 to the second cavity 17. The partition wall 13 extends downwards from a top portion 111 of the container 11, and is configured for blocking the working fluid 40 from flowing from the first cavity 16 to the second cavity 17. The inlet 14 and the outlet 15 at placed at two opposite side walls 112 of the container 11 in communication with the cavities 16, 17 respectively.

The wick layer 12 is configured for guiding the working liquid 40 to flow from the first cavity 16 to the second cavity 17. The wick layer 12 is formed as a porous capillary structure. For example, the wick layer 12 may be comprised of carbon nanotubes. The wick layer 12 is placed on the bottom plate 113 of the container 11. The wick layer 12 is extended from the first cavity 16 to the second cavity 17 so as to allow a working liquid 40 to flow from the first cavity 16 to the second cavity 17, or vice versa, by capillary action. A thickness of the wick layer 12 may be in a range from 0.1 millimeters to 0.5 millimeters. Preferably, the thickness of the wick layer 12 is in a range from 0.2 millimeters to 0.3 millimeters.

The heat dissipating module 10 can be placed on an electronic device 60 for absorbing the generated heat. Due to absorption of the heat generated by an electronic device 60, the coolant liquid 40 becomes vapor phase coolant 40′ in the second cavity 17. A gasket 50 may be sandwiched between the heat dissipating module 10 and the electronic device 60 for reducing the thermal resistance. The gasket 50 is selected from materials with high thermal resistance and flexibility, such as flexible graphite.

Referring to FIG. 2, a heat sink assembly 100 in accordance with the preferred embodiment of the present invention is shown. The heat sink assembly 100 includes an above-described heat dissipating module 10, a circulatory tube 20, and a cooling device 30. A working fluid 40 may be filled in the circulatory tube 20. The heat dissipating module 10 is mounted on an electronic device 60 for absorbing heat generated by the electronic device 60. The circulatory tube 20 is comprised of a metal selected from the group consisting of copper, aluminum, nickel, stainless steel and any combination alloy thereof. The circulatory tube 20 is connected with the heat dissipation device 10 and the cooling device 30 for transporting the coolant 40 between the heat dissipating module 10 and the cooling device 30. The working fluid 40 may be any medium that can be passed through the heat sink assembly 100 in order to take heat away, including but not limited to, water, water with additives, air, high-density gas or any other gas or liquid. The cooling device 30 further includes a fan 31 and a number of fins 32.

Compared with conventional heat sink using coolant, the present heat dissipating module 10 can separate the cooling fluid 40 and the vapor of the cooling fluid 40′ by the partition wall 13. Because the vapor of the cooling fluid 40′ can flow freely without resistance from the cooling fluid 40, the present heat dissipating module 10 has good heat dissipation efficiency.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

I claim:

1. A heat dissipating module comprising:
a container comprising
a partition wall;
first and second cavities separated by the partition wall; and
an inlet and an outlet respectively in communication with the first and second cavities;
a wick layer extending from the first cavity to the second cavity; and
a working fluid received in the first cavity.

2. The heat dissipating module as claimed in claim 1, wherein the partition wall is arranged inside the container, configured for blocking the working fluid from flowing from the first cavity to the second cavity.

3. The heat dissipating module as claimed in claim 2, wherein the wick layer is configured for guiding the working liquid to flow from the first cavity to the second cavity.

4. The heat dissipating module as claimed in claim 1, further comprising a heat generating device with the heat dissipating module being mounted thereon.

5. The heat dissipating module as claimed in claim 1, wherein the container is comprised of a metal selected from the group consisting of copper, aluminum, nickel, stainless steel and any combination alloy thereof.

6. The heat dissipating module as claimed in claim 1, wherein the wick layer has a porous capillary structure.

7. The heat dissipating module as claimed in claim 6, wherein the wick layer is comprised of carbon nanotubes.

8. The heat dissipating module as claimed in claim 1, wherein a thickness of the wick layer is in a range of 0.1 to 0.5 millimeters.

9. The heat dissipating module as claimed in claim 1, wherein a thickness of the wick layer is in a range of 0.2 to 0.3 millimeters.

10. A heat sink assembly comprising:
a heat dissipating module as claimed in claim 1;
a circulatory tube having one end thereof inserted into an inlet of the heat dissipating module and another end thereof inserted into an outlet of the heat dissipating module; and
a cooling device configured for cooling the working liquid in the circulatory tube.

11. The heat sink assembly as claimed in claim 10, wherein the circulatory tube is comprised of a metal selected from the group consisting of copper, aluminum, nickel, stainless steel and any combination alloy thereof.

12. The heat sink assembly as claimed in claim 10, wherein the cooling device is a heat sink with a fan.
